(19) United States
(12) Patent Application Publication
(10) Pub. No.: US 2025/0268041 A1
(43) Pub. Date: Aug. 21, 2025

(54) DISPLAY DEVICE

(71) Applicant: Japan Display Inc., Tokyo (JP)

(72) Inventors: Hideyuki TAKAHASHI, Tokyo (JP); Sho YANAGISAWA, Tokyo (JP); Yasuhito ARUGA, Tokyo (JP)

(73) Assignee: Japan Display Inc., Tokyo (JP)

(21) Appl. No.: 19/050,164

(22) Filed: Feb. 11, 2025

(30) Foreign Application Priority Data
Feb. 19, 2024 (JP) 2024-022859

(51) Int. Cl. H10K 59/131

(52) U.S. Cl. CPC H10K 59/131

(57) ABSTRACT

According to one embodiment, a display device includes a first inorganic insulating layer, an organic insulating layer disposed on the first inorganic insulating layer, a second inorganic insulating layer disposed on the organic insulating layer and overlapping a peripheral area of a lower electrode, an organic layer disposed on the lower electrode, first metal layers disposed on the first inorganic insulating layer in a peripheral area, and second metal layers electrically connected to the first metal layers. The second metal layers include a pad portion. The second inorganic insulating layer is in contact with the first inorganic insulating layer in an area overlapping the pad portion.

### CROSS-REFERENCE TO RELATED APPLICATION

This application is based upon and claims the benefit of priority from Japanese Patent Application No. 2024-022859, filed Feb. 19, 2024, the entire contents of which are incorporated herein by reference.

### FIELD

Embodiments described herein relate generally to a display device.

### BACKGROUND

In recent years, display devices in which organic light emitting diodes (OLEDs) are applied as display elements have been put to practical use. These display elements comprise a pixel circuit that contains a thin-film transistor, a lower electrode connected to the pixel circuit, an organic layer that covers the lower electrode, and an upper electrode that covers the organic layer. The organic layer includes a light emitting layer and, in addition, functional layers such as a hole transport layer and an electron transport layer. In such display devices, there is a need for technology to suppress a decrease in reliability.

### BRIEF DESCRIPTION OF THE DRAWINGS

FIG. 1 is a diagram showing a configuration example of a display device according to the first embodiment.

FIG. 2 is a diagram showing an example of layout of subpixels.

FIG. 3 is a cross-sectional view schematically showing the display device taken along the line III-III in FIG. 2.

FIG. 4 is a plan view showing a configuration example of a region including a plurality of pads in the display device shown in FIG. 1.

FIG. 5 is a plan view showing a configuration example of a region including a plurality of pads in the display device shown in FIG. 1.

FIG. 6 is a plan view showing a metal layer shown in FIG. 5.

FIG. 7 is a cross-sectional view showing the display device taken along the line VII-VII in FIG. 5.

FIG. 8 is a cross-sectional view showing the display device taken along the line VIII-VIII in FIG. 5.

FIG. 9 is a plan view showing a configuration example of a region including a plurality of pads in a display device according to a comparative example.

FIG. 10 is a cross-sectional view showing the display device taken along the line X-X in FIG. 9.

FIG. 11 is a cross-sectional view showing the display device taken along the line XI-XI in FIG. 9.

FIG. 12 is a plan view showing a configuration example of a region including a plurality of pads in a display device according to the second embodiment.

FIG. 13 is a cross-sectional view showing the display device taken along the line XIII-XIII in FIG. 12.

FIG. 14 is a cross-sectional view showing the display device taken along the line XIV-XIV in FIG. 12.

### DETAILED DESCRIPTION

In general, according to one embodiment, a display device comprises a substrate, a first inorganic insulating layer disposed above the substrate and over a display area in which a plurality of display elements are disposed and a peripheral area which surrounds the display area, an organic insulating layer disposed on the first inorganic insulating layer, a lower electrode disposed on the organic insulating layer in the display area, a second inorganic insulating layer disposed on the organic insulating layer and overlapping a circumferential edge portion of the lower electrode, an organic layer including a light emitting layer and disposed on the lower electrode, an upper electrode disposed on the organic layer, a plurality of first metal layers disposed on the first inorganic insulating layer and aligned along an end of the substrate, in the peripheral region and a plurality of second metal layers electrically connected to the first metal layers above the second inorganic insulating layer in the peripheral region. The second metal layer includes pad portions extending toward the end of the substrate beyond the first metal layer. The second inorganic insulating layer is in contact with the first inorganic insulating layer in an area overlapping the pad portions.

With configurations such as described above, it is possible to provide a display device which can suppress the increase in reliability.

Embodiments will be described hereinafter with reference to the accompanying drawings. Note that the disclosure is merely an example, and proper changes within the spirit of the invention, which are easily conceivable by a skilled person, are included in the scope of the invention as a matter of course.

In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as a first direction X, a direction along the Y axis is referred to as a second direction Y and a direction along the Z axis is referred to as a third direction Z. Further, viewing the constitutional elements parallel to the Z direction is referred to as plan view.

In the following explanations, the expression “overlapping” refers not only to cases where other elements overlap the target element from the third direction Z, but also to cases where other elements overlap the target element from a direction opposite to the third direction Z. Further, the expression “overlapping” refers not only to cases where the target elements are directly in contact with each other, but also to cases where the target elements are spaced apart from each other or where some other element is located between the target elements.

The display device of each of the embodiments is an organic electroluminescent display device equipped with an organic light emitting diode (OLED) as a display element, and can be mounted in various electronic devices such as TVs, personal computers, in-vehicle equipment, tablet terminals, smartphones, cell phone terminals, wearable terminals and the like.

### First Embodiment

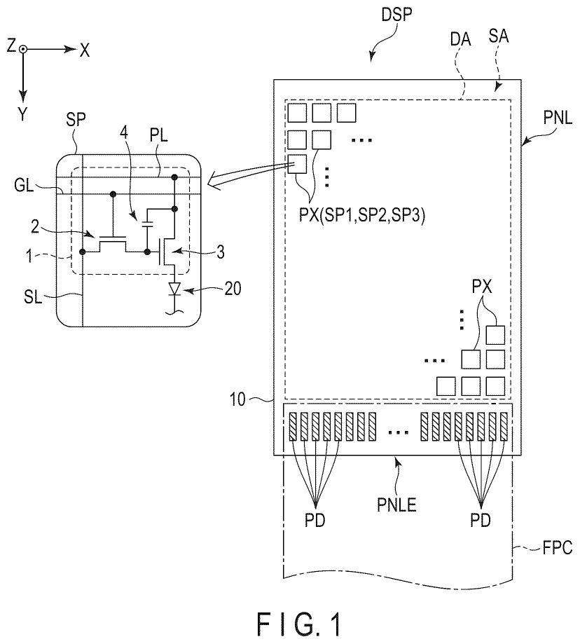

FIG. 1 is a diagram showing a configuration example of a display device DSP according to this embodiment. The display device DSP comprises a display panel PNL. The display panel PNL includes an insulating substrate 10. The substrate 10 may be glass or a flexible resin film.

In this embodiment, the shape of the substrate 10 is rectangular that is elongated along the second direction Y when viewed in plan view. Note here that the shape of the substrate 10 in plan view is not limited to rectangular, and may as well be some other shape such as square, circle or oval.

The display panel PNL includes a display area DA that displays images and a peripheral area SA around the display area DA on the substrate 10. The display area DA comprises a plurality of pixels PX arranged along a matrix along the first direction X and the second direction Y.

The pixels PX each include a plurality of subpixels SP. For example, each of the pixels PX contains a subpixel SP1 of a first color, a subpixel SP2 of a second color, and a subpixel SP3 of a third color. The first color, the second color, and the third color are different from each other. Note that each of the pixels PX may as well contain a subpixel SP of another color such as white, together with the subpixels SP1, SP2, and SP3, or in place of any of the subpixels SP1, SP2, and SP3.

The subpixel SP comprises a pixel circuit 1 and a display element 20 driven by the pixel circuit 1. The pixel circuit 1 comprises a pixel switch 2, a drive transistor 3, and a capacitor 4. The pixel switch 2 and the drive transistor 3 are switching elements, for example, constituted by thin film transistors.

A gate electrode of the pixel switch 2 is connected to a respective scanning line GL. One of a source electrode and a drain electrode of the pixel switch 2 is connected to a respective signal line SL, and the other is connected to the gate electrode of the drive transistor 3 and the capacitor 4. In the drive transistor 3, one of the source electrode and the drain electrode is connected to a power supply line PL and the capacitor 4, and the other is connected to an anode of the display element 20.

Note that the configuration of the pixel circuit 1 is not limited to that of the example illustrated in the figure. For example, the pixel circuit 1 may as well contain more thin film transistors and capacitors. The display element 20 is an organic light emitting diode (OLED) as a light emitting element, and may as well be referred to as an organic EL element.

The display device DSP has a plurality of pads PD in the peripheral area SA. The plurality of pads PD constitute, for example, a pad for the touch panel. The plurality of pads PD are arranged in one direction along a panel edge PNLE. Here, the edge includes the end and the region in the vicinity thereof. The panel edge PNLE includes an edge of the substrate 10. In this embodiment, the direction along the edge of the substrate 10 corresponds to the first direction X.

Each of the pads PD extends along the second direction Y, but configuration is not limited to this. For example, some of the plurality of pads PD may as well extend in a diagonal direction. The pads PD are, for example, constituted by at least one of metal layers, which will be described later. These pads PD are electrically connected to, for example, a flexible printed circuit board FPC shown by dotted lines.

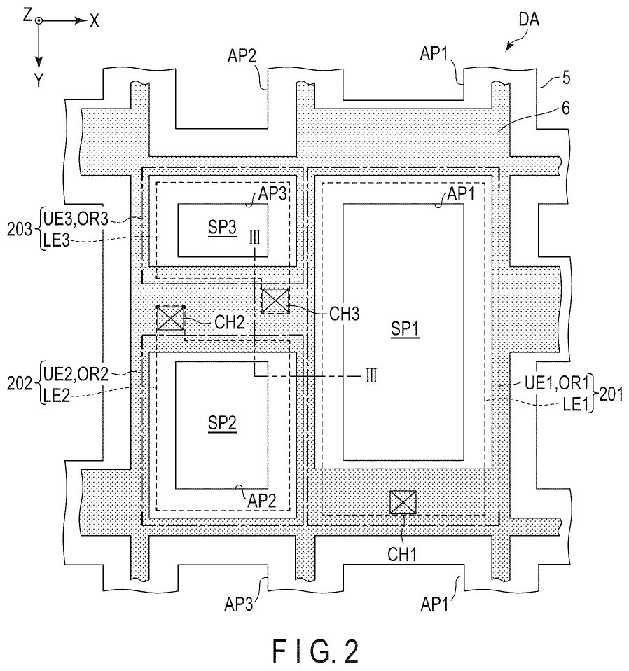

FIG. 2 shows an example of the layout of subpixels SP1, SP2, and SP3. In the example illustrated in FIG. 2, the subpixel SP2 and the subpixel SP3 are aligned along the second direction Y. The subpixel SP1 and the subpixel SP2 are aligned along the first direction X, and the subpixel SP1 and the subpixel SP3 are aligned along the first direction X.

When the subpixels SP1, SP2, and SP3 are arranged in such a layout as described above in the display area DA, rows in which subpixels SP2 and subpixels SP3 are arranged alternately along the second direction Y, and rows in which a plurality of subpixels SP1 are arranged along the second direction Y are formed. These rows are arranged alternately along the first direction X.

Note here that the layout of the subpixels SP1, SP2, and SP3 is not limited to that of the example illustrated in FIG. 2. As another example, the subpixels SP1, SP2, and SP3 in each pixel PX may as well be disposed in order along the first direction X.

In the display area DA, an insulating layer 5 and a partition 6 are provided. In this embodiment, the partition corresponds to a first partition. The insulating layer 5 has apertures AP1, AP2, and AP3 in the subpixels SP1, SP2, and SP3, respectively. The insulating layer 5 with these apertures AP1, AP2, and AP3 may as well be referred to as a rib in some cases.

The partition 6 overlaps the insulating layer in plan view. The partition 6 is formed into a grid pattern surrounding the apertures AP1, AP2, and AP3. It may as well be said that the partition 6 have apertures in the subpixels SP1, SP2, and SP3 as in the case of the insulating layer 5.

The subpixels SP1, SP2, and SP3 comprise display elements 201, 202, and 203, respectively, as the display elements 20. The display element 201 of the subpixel SP1 has a lower electrode LE1, an upper electrode UE1, and an organic layer OR1 each overlapping the respective aperture AP1. Circumferential edge portions of the lower electrode LE1, the organic layer OR1, and the upper electrode UE1 overlap the insulating layer 5 in plan view. Note here that the circumferential edge portions include the edges and the regions in the vicinity thereof.

The display element 202 of the subpixel SP2 comprises a lower electrode LE2, an upper electrode UE2, and an organic layer OR2 each overlapping the respective aperture AP2. The circumferential edge portions of the lower electrode LE2, the organic layer OR2, and the upper electrode UE2 overlap the insulating layer 5 in plan view.

The display element 203 of the subpixel SP3 comprises a lower electrode LE3, an upper electrode UE3, and an organic layer OR3 each overlapping the respective aperture AP3. The circumferential edge portions of the lower electrode LE3, the organic layer OR3, and the upper electrode UE3 overlap the insulating layer 5 in plan view.

In the example illustrated in FIG. 2, the outlines of the lower electrodes LE1, LE2, and LE3 are indicated as dotted lines, and the outlines of the organic layers OR1, OR2, and OR3 and the upper electrodes UE1, UE2, and UE3 are indicated as alternate long and short dash lines. Note that the outlines of the lower electrodes, the organic layers, and the upper electrodes shown in the figure may not necessarily be those reflected by the actual shapes.

The lower electrodes LE1, LE2, and LE3 correspond to the anodes of the display elements, for example. The upper electrodes UE1, UE2, and UE3 correspond to the cathodes or common electrodes of the display elements, respectively.

The lower electrode LE1 is connected to the pixel circuit 1 of the subpixel SP1 (as shown in FIG. 1) via a contact hole CH1. The lower electrode LE2 is connected to the pixel circuit 1 of the subpixel SP2 via a contact hole CH2. The lower electrode LE3 is connected to the pixel circuit 1 of the subpixel SP3 via a contact hole CH3.

In the example illustrated in FIG. 2, the areas of the apertures AP1, AP2, and AP3 are different from each other. The area of the aperture AP1 is larger than the area of the aperture AP2, and the area of the aperture AP2 is larger than the area of the aperture AP3. In other words, the area of the lower electrode LE1 exposed through the aperture AP1 is larger than the area of the lower electrode LE2 exposed through the aperture AP2, and the area of the lower electrode LE2 exposed through the aperture AP2 is larger than the area of the lower electrode LE3 exposed through the aperture AP3.

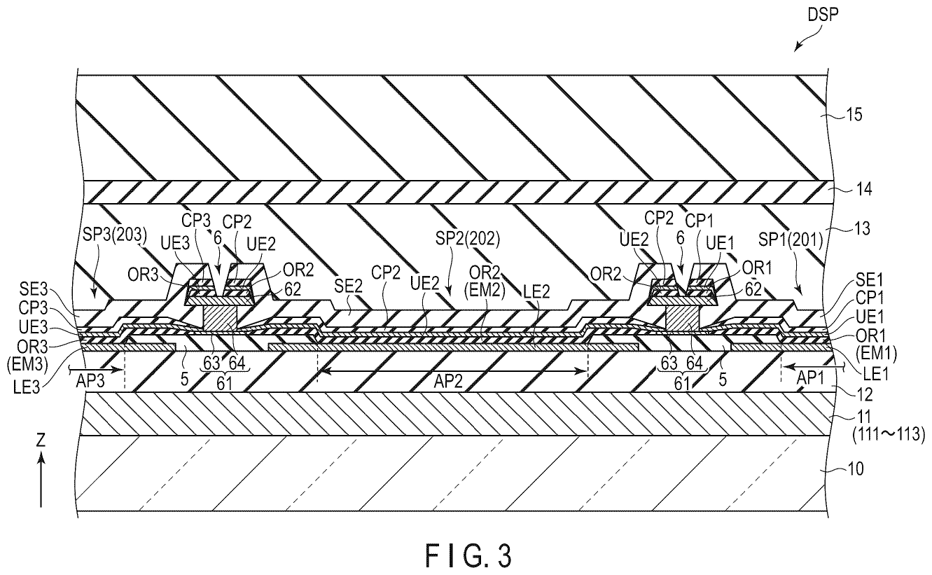

FIG. 3 is a cross-sectional view schematically showing the display device DSP taken along the line III-III in FIG. 2. The circuit layer 11 is disposed on the substrate 10. The circuit layer 11 includes various circuits such as the pixel circuit 1 and the like and various wiring such as the scanning line GL, the signal line SL, and the power line PL, shown in FIG. 1.

The circuit layer 11 is covered by the insulating layer 12. The insulating layer 12 is disposed on the circuit layer 11. The insulating layer 12 has a function of planarizing the projections and recesses caused by the circuit layer 11. The insulating layer 12 is an organic insulating layer.

The lower electrodes LE1, LE2, and LE3 are disposed on the insulating layer 12 and are separated from each other. The insulating layer 5 is disposed on the insulating layer 12 and the lower electrodes LE1, LE2, and LE3. The insulating layer 5 is an inorganic insulating layer. In this embodiment, the insulating layer 5 corresponds to the second inorganic insulating layer.

The aperture AP1 of the insulating layer 5 overlaps the lower electrode LE1, the aperture AP2 overlaps the lower electrode LE2, and the aperture AP3 overlaps the lower electrode LE3. The circumferential edge portions of the lower electrodes LE1, LE2, and LE3 are covered by the insulating layer 5.

The lower electrodes LE1, LE2, and LE3 are connected to the respective pixel circuits 1 of the subpixels SP1, SP2, and SP3 via respective contact holes formed in the insulating layer 12. The contact holes in the insulating layer 12 are omitted from the illustration in FIG. 3, but correspond to the contact holes CH1, CH2, and CH3 in FIG. 2, respectively.

The partition 6 is disposed between each adjacent pair of display elements on the insulating layer 5. More specifically, the partition 6 illustrated in the right side of the figure is disposed between display elements 201 and 202 adjacent to each other, whereas the partition 6 illustrated in the left side of the figure is disposed between display elements 202 and 203 adjacent to each other.

The partition 6 includes an electrically conductive lower portion 61 disposed on the insulating layer 5 and an upper portion 62 disposed on the lower portion 61. The lower portion 61 of the partition 6 shown on the right side of the figure is located between the aperture API and the aperture AP2. The lower portion 61 of the partition 6 shown on the left side of the figure is located between the aperture AP2 and the aperture AP3.

The lower portion 61 may be a single layer or a multi-layered body. The upper portion 62 has a width larger than that of the lower portion 61. Both end portions of the upper portion 62 protrude beyond the respective side surfaces of the lower portion 61. Such a shape of the partition 6 is referred to as an overhang shape.

In the example illustrated in FIG. 3, the lower portion 61 has a bottom layer 63 disposed on the insulating layer 5 and an axial layer 64 disposed on the bottom layer 63. For example, the bottom layer 63 is formed thinner than the axial layer 64. Further, in the example illustrated in FIG. 3, both end portions of the bottom layer 63 protrude from the respective side surfaces of the axial layer 64.

The organic layer OR1 is brought into contact with the lower electrode LE1 via the aperture AP1 so as to cover the lower electrode LE1, which is exposed through the aperture AP1, and the circumferential edge portion is located on the insulating layer 5. The upper electrode UE1 covers the organic layer OR1 and is brought into contact with the lower portion 61.

The organic layer OR2 is brought into contact with the lower electrode LE2 via the aperture AP2 so as to cover the lower electrode LE2 which is exposed through the aperture AP2, and the circumferential edge portion is located on the insulating layer 5. The upper electrode UE2 covers the organic layer OR2, and is in contact with the lower electrode LE2.

The organic layer OR3 is brought into contact with the lower electrode LE3 via the aperture AP3 so as to cover the lower electrode LE3 which is exposed through the aperture AP3, and the circumferential edge portion is located on the insulating layer 5. The upper electrode UE3 covers the organic layer OR3, and is in contact with the lower 61.

In the example illustrated in FIG. 3, the subpixel SP1 includes a cap layer CP1 and a sealing layer SE1, the subpixel SP2 includes a cap layer CP2 and a sealing layer SE2, and the subpixel SP3 includes a cap layer CP3 and a sealing layer SE3. The cap layers CP1, CP2, and CP3 each serve as an optical adjustment layer that improve the light extraction efficiency of the light emitted from the respective one of the organic layers OR1, OR2, and OR3.

The cap layer CP1 is disposed on the upper electrode UE1. The cap layer CP2 is disposed on the upper electrode UE2. The cap layer CP3 is disposed on the upper electrode UE3.

The sealing layer SE1 is disposed on the cap layer CP1, is brought into contact with the partition 6, and continuously covers the elements of the subpixel SP1. The sealing layer SE2 is disposed on the cap layer CP2, is brought into contact with the partition 6, and continuously covers the elements of the subpixel SP2. The sealing layer SE3 is disposed on the cap layer CP3, is brought into contact with the partition 6, and continuously covers the elements of the subpixel SP3.

In the example illustrated in FIG. 3, respective parts of the organic layer OR1, the upper electrode UE1, and the cap layer CP1 are located on the partition 6 which surrounds the subpixel SP1. These parts are separated from the portions of the organic layer OR1, the upper electrode UE1, and the cap layer CP1, which are located in the aperture AP1 (that is, the portions that constitute the display element 201).

Similarly, respective parts of the organic layer OR2, the upper electrode UE2 and the cap layer CP2 are located on the partition 6 surrounding the subpixel SP2. These parts are separated from the portions of the organic layer OR2, the upper electrode UE2 and the cap layer CP2 which are located in the aperture AP2 (that is, the portions that constitute the display element 202).

Similarly, respective parts of the organic layer OR3, the upper electrode UE3 and the cap layer CP3 are located on the partition 6 surrounding the subpixel SP3, and these parts are separated from the portions of the organic layer OR3, the upper electrode UE3 and the cap layer CP3 which are located in the aperture AP3 (portions that constitute the display element 203).

The end portions of the sealing layers SE1, SE2, and SE3 are located on the partition 6. In the example illustrated in FIG. 3, the end portions of the sealing layers SE1 and SE2, which are located on the partition 6 between the subpixels SP1 and SP2, are separated from each other, and the end portions of the sealing layers SE2 and SE3, which are located on the partition 6 between the subpixels SP2 and SP3, are separated from each other.

The sealing layers SE1, SE2, and SE3 are covered by the resin layer 13. The resin layer 13 is covered by the sealing layer 14. The sealing layer 14 is covered by the resin layer 15.

The insulating layer 5, the sealing layers SE1, SE2, and SE3, and the sealing layer 14 are each formed, for example, of any one of inorganic insulating materials such as silicon nitride (SiNₓ), silicon oxide (SiOₓ), silicon oxynitride (SiON), and aluminum oxide (Al₂O₃).

The bottom layer 63 and the axial layer 64 of the partition 6 are formed of a metal material. As the metal material for the bottom layer 63, for example, molybdenum, titanium, titanium nitride (TiN), molybdenum-tungsten alloy (MoW) or molybdenum-niobium alloy (MoNb) can be used.

As the metal material of the axial layer 64, for example, aluminum, aluminum-neodymium alloy (AlNd), aluminum-yttrium alloy (AlY), or aluminum-silicon alloy (AlSi) can be used. Note that the axial layer 64 may as well be formed of an insulating material.

For example, the upper portion 62 of the partition 6 has a stacked layer structure constituted by a lower layer formed of a metal material and an upper layer formed of a conductive oxide. As the metal material for forming the lower layer, for example, titanium, titanium nitride, molybdenum, tungsten, molybdenum-tungsten alloy or molybdenum-niobium alloy can be used.

As the conductive oxide for forming the upper layer, for example, indium tin oxide (ITO) or indium zinc oxide (IZO) can be used. Note here that the upper portion 62 may as well have a single-layer structure of a metal material. Further, the upper portion 62 may include a layer formed of an insulating material.

The lower electrodes LE1, LE2, and LE3 are stacked-layered body that includes a transparent electrode formed of an oxide conductive material such as ITO and a metal electrode formed of a metal material such as silver.

The organic layer OR1 includes a light emitting layer EM1. The organic layer OR2 includes a light emitting layer EM2. The organic layer OR3 includes a light emitting layer EM3. The light emitting layer EM1, light emitting layer EM2, and light emitting layer EM3 are formed from materials different from each other.

In one example, the light emitting layer EM1 is formed of a material that emits light in a blue wavelength range, the light emitting layer EM2 is formed of a material that emits light in a green wavelength range, and the light emitting layer EM3 is formed of a material that emits light in a red wavelength range. Further, each of the organic layers OR1, OR2, and OR3 includes a plurality of functional layers such as a hole injection layer, a hole transport layer, an electron blocking layer, a hole blocking layer, an electron transport layer, an electron injection layer and the like.

The upper electrodes UE1, UE2, and UE3 are formed, for example, of a metal material such as an alloy of magnesium and silver (MgAg). The cap layers CP1, CP2, and CP3 are each a stacked-layered body of a plurality of thin films. All of the plurality of thin films are transparent and have refractive indices different from each other.

The circuit layer 11, the insulating layer 12, and the insulating layer 5 shown in FIG. 3 are disposed on the display area DA and over to the peripheral area SA.

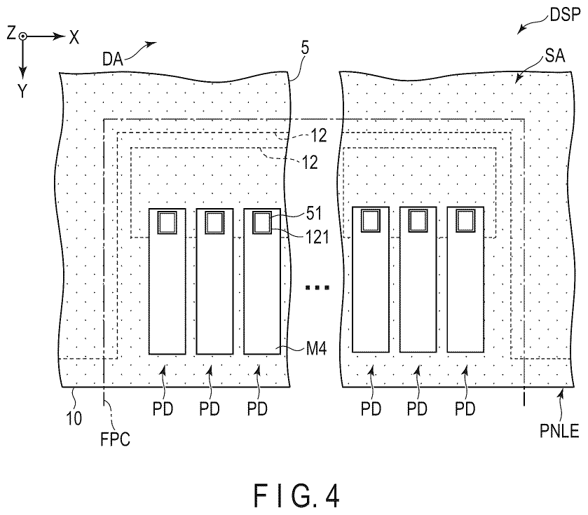

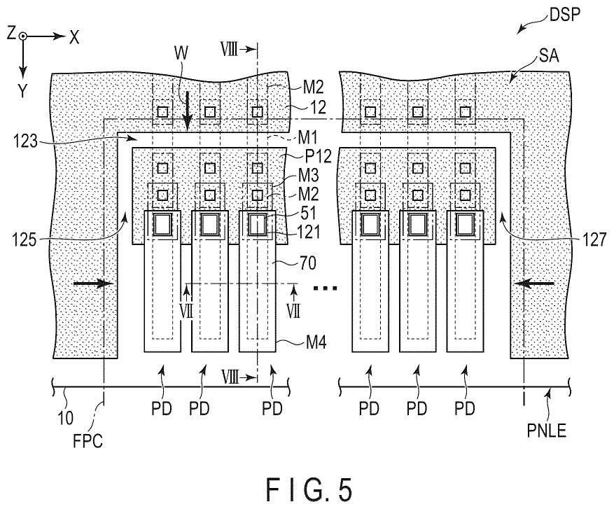

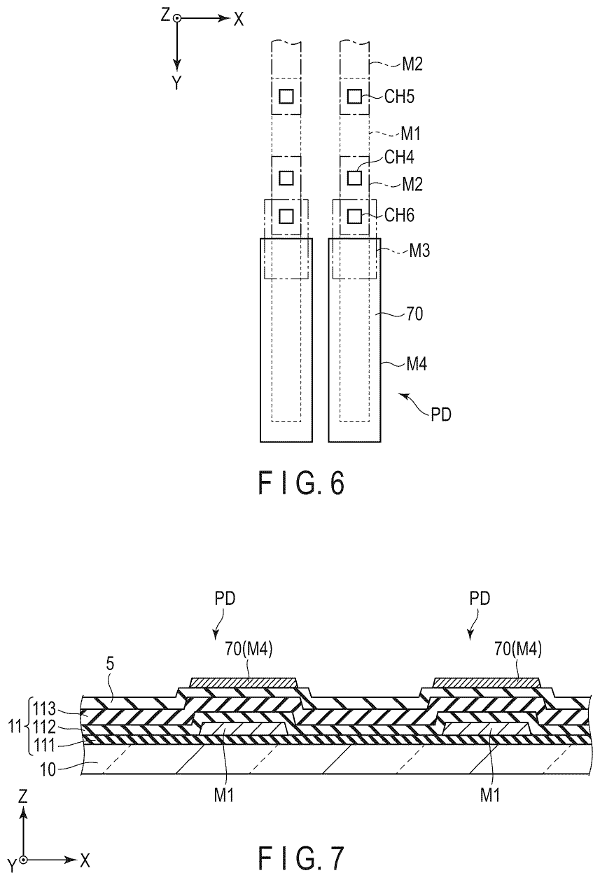

FIGS. 4 and 5 are each a plan view showing a configuration example of a region including a plurality of pads PD of the display device DSP shown in FIG. 1. FIG. 6 is a plan view showing the metal layers M1, M2, M3, and M4 shown in FIG. 5.

FIGS. 4 and 5 show the vicinity of the panel edge PNLE in the peripheral area SA. In FIGS. 4 and 5, the display area DA is formed in the upper part of the figure. In FIGS. 4 and FIG. 5, the flexible printed circuit board FPC shown in FIG. 1 is indicated by dotted lines. In FIG. 5, the insulating layer 5 is omitted from the configuration example illustrated in FIG. 4.

As shown in FIGS. 4 and 5, the plurality of pads PD are aligned along the first direction X and extend along the second direction Y. As described above, the insulating layer 5 and the insulating layer 12 are formed over to the region (the peripheral area SA) including the pads PD.

As shown in FIG. 4, the insulating layer 5 is formed to extend to the panel edge PNLE. In contrast, the insulating layer 12 is not formed to extend to the panel edge PNLE, as shown in FIG. 5.

The insulating layer 5 has apertures 51 as shown in FIG. 4. The insulating layer 12 has apertures 121 as shown in FIG. 5. In this embodiment, the apertures 51 correspond to the second apertures, and the apertures 121 correspond to the first apertures. The apertures 51 of the insulating layer 5 overlap the apertures 121 of the insulating layer 12, respectively.

The apertures 51 of the insulating layer 5 and the apertures 121 of the insulating layer 12 each have a rectangular shape elongated along the second direction Y. The area of each aperture 121 of the insulating layer 12 is larger than the area of the respective aperture 51 of the insulating layer 51 in plan view. The edge of each aperture 121 is located on an outer side the respective edge of the respective aperture 51.

The display device DSP further comprises a plurality of metal layers M1, M2, M3, and M4, as shown in FIG. 6. In this embodiment, the metal layer M1 corresponds to a fourth metal layer, the metal layer M2 corresponds to a third metal layer, the metal layer M3 corresponds to a first metal layer, and the metal layer M4 corresponds to a second metal layer.

Each of the metal layers M1, M2, M3, and M4 extends along the second direction Y. The metal layers M1, M2, M3, and M4, respectively adjacent to each other, are arranged along the first direction X at intervals therebetween.

The insulating layer 12 includes a cover portion P12 that covers the plurality of metal layers M3, as shown in FIG. 5. The cover portion P12 has a shape elongated along the first direction X (for example, a rectangular shape).

The insulating layer 12 has slits 123, 125, and 127 in the peripheral area SA, as shown in FIG. 5. The cover portion P12 is separated from the insulating layer 12 formed therearound via the slits 123, 125, and 127. In other words, the cover portion P12 is independent of the insulating layer 12 formed therearound. Note here that the insulating layer 12 formed therearound includes the insulating layer 12 formed on the display area DA side.

The slit 123 is located between the display area DA, which includes the lower electrodes LE1, LE2, LE3, and the metal layer M4. The slit 123 is formed along the first direction X. The width of the slit 123 along the first direction X is greater than the distance between the metal layers M4 disposed at respective end portions thereof along the first direction X.

The slits 125 and 127 are connected to the respective end portions of the slit 123 along the first direction X. In the second direction Y, the slits 125 and 127 are formed from the slit 123 towards the panel edge PNLE. Further, between the cover portion P12 and an end of the substrate 10, an area is formed where the insulating layer 12 is not formed along the second direction Y.

In the example shown in FIGS. 4 and 5, each aperture 51 and each aperture 121 overlap one respective single metal layer M4. The metal layer M4 includes a pad portion 70, as shown in FIG. 5.

Each pad portion 70 corresponds to a portion extending in the second direction Y (the panel edge PNLE) beyond the metal layer M3. The pad portion 70 is located between the apertures 51 and 121, and the panel edge PNL along the second direction Y. Each pad PD is mainly constituted by the pad portion 70 of the metal layer M4.

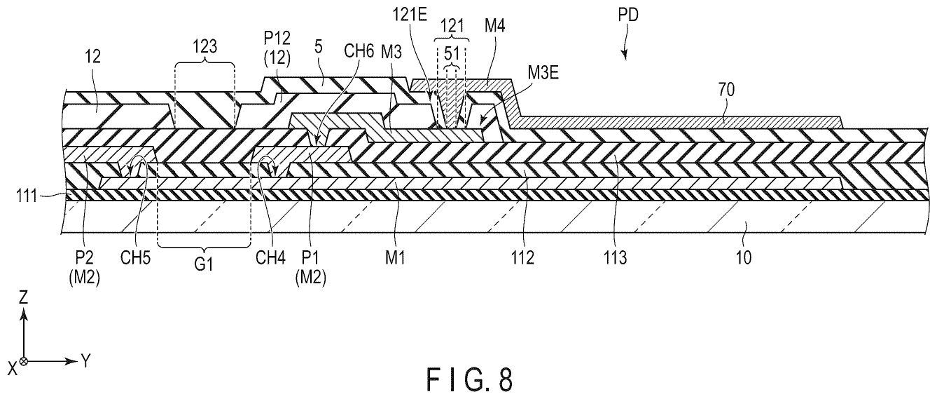

FIG. 7 is a cross-sectional view of the display device DSP taken along the line VII-VII in FIG. 5. FIG. 8 is a cross-sectional view of the display device DSP taken along the line VIII-VIII in FIG. 5. The circuit layer 11 includes insulating layers 111, 112, and 113. The metal layers M1 and M2 described above, together with the insulating layers 111, 112, and 113, constitute the circuit layer 11.

The insulating layer 111 is an inorganic insulating layer and is disposed on the substrate 10. The metal layer M1 is disposed on the insulating layer 111. The metal layer M1 is formed in the same layer as that of the scanning lines GL, for example.

The insulating layer 112 is an inorganic insulating layer and is disposed on the insulating layer 111 and the metal layer M1. The insulating layer 112 has contact holes CH4 and CH5 as shown in FIG. 8.

The metal layer M2 is disposed on the insulating layer 112. In another point of view, the metal layer M1 is disposed between the substrate 10 and the metal layer M2. The metal layer M2 is formed in the same layer as that of the signal lines SL, for example. When focusing on the slit 123, the metal layer M2 does not overlap the slit 123, as shown in FIG. 8.

The metal layer M2 is electrically connected to the metal layer M1 via the contact holes CH4 and CH5. More specifically, the metal layer M2 includes a first portion P1 connected to the metal layer M1 via the contact hole CH4 and a second portion P2 connected to the metal layer M1 via the contact hole CH5.

The second portion P2 extends toward the display area DA. The first portion P1 is aligned with the second portion P2 along the second direction Y with an interval therebetween. In other words, a gap G1 is formed between the first portion P1 and the second portion P2.

The gap G1 overlaps the slit 123. In the example illustrated in FIG. 8, the length of the slit 123 along the second direction Y is less than the length of the gap G1 along the second direction Y. A part of the metal layer M1 overlaps the slit 123 while the gap G1 interposed therebetween.

The insulating layer 113 is an inorganic insulating layer, and is disposed on the insulating layer 112 and the metal layer M2. In another point of view, the metal layer M2 is disposed between the substrate 10 and the insulating layer 113. In this embodiment, the insulating layer 113 corresponds to a first inorganic insulating layer. The insulating layer 113 has a contact hole CH6.

The metal layer M3 is disposed on the insulating layer 113. The metal layer M3 is electrically connected to the metal layer M2. More specifically, the metal layer M3 is in contact with the first portion Pl of the metal layer M2 via the contact hole CH6.

The insulating layer 12 is disposed on the insulating layer 113 and the metal layer M3. The cover portion P12 of the insulating layer 12 covers the metal layer M3, as shown in FIG. 8. More specifically, the cover portion P12 covers a circumferential edge portion M3E of the metal layer M3. With this configuration, the circumferential edge portion M3E of the metal layer M3 is not exposed from the cover portion P12. The aperture 121 overlaps the metal layer M3 in the cover portion P12.

The insulating layer 5 is disposed on the insulating layers 12 and 113 and the cover portion P12. The insulating layer 113 is exposed from the insulating layer 12 in the slit 123, as shown in FIG. 8.

The insulating layer 113 is covered by the insulating layer 5 in the slit 123. In other words, the insulating layer 5 is in contact with the insulating layer 113 in the slit 123. Although not shown in FIGS. 7 and 8, the insulating layer 5 is in contact with the insulating layer 113 in the slits 127 and 129 as well. The metal layer M4 is located above the

insulating layer 5. More specifically, the metal layer M4 is disposed on the insulating layer 5. The metal layer M4 is in contact with the metal layer M3, which is exposed from the aperture 51 of the insulating layer 5. In other words, the metal layer M4 is electrically connected to the metal layer M3 via the apertures 51 and 121.

Focusing on the pad portion 70, the insulating layer 5 is disposed between the pad portion 70 and the insulating layer 113. More specifically, the insulating layer 5 is in contact with the insulating layer 113 in an area that overlaps the pad portion 70 along the third direction Z. Further, in this embodiment, the insulating layer 5 is in contact with the pad portion 70 in the area.

As shown in FIG. 7, the insulating layer 5 is in contact with the insulating layer 113 between each adjacent pair of pad portions 70. In other words, there is no insulating layer 12 formed between each adjacent pair of pad portions 70.

The metal layer M1 extends toward the panel edge PNLE beyond the metal layer M3, as shown in FIG. 8. The pad portion 70 overlaps the metal layer M1 along the third direction Z. The insulating layer 5 covers a circumferential edge portion 121E of each aperture 121 of the insulating layer 12, as shown in FIG. 8. The insulating layer 12 is not exposed from the insulating layer 5. With this configuration, the metal layer M4 is not brought into contact with the insulating layer 12.

The insulating layers 111, 112, and 113 are formed of one of silicon oxide, silicon nitride, and silicon oxynitride. The metal layers M2, M3, and M4 are each formed from a plurality of layers, for example.

In one example, at least one of the metal layers M2, M3, and M4 includes two titanium layers formed from titanium-based materials and an aluminum layer formed from an aluminum-based material located between the two titanium layers. Note that at least one of the metal layers M2, M3, and M4 may be formed by placing an aluminum layer between layers formed from molybdenum-based materials.

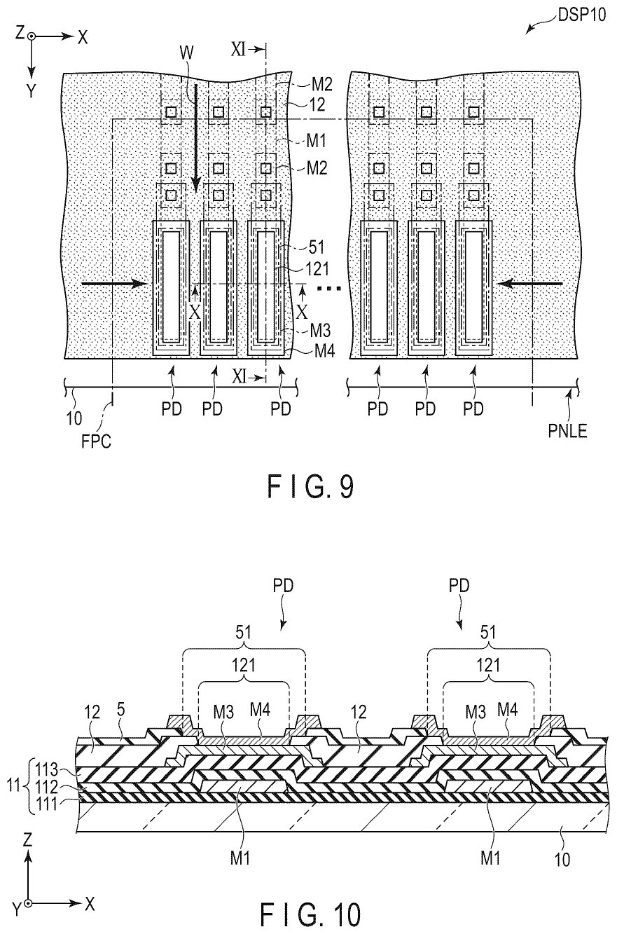

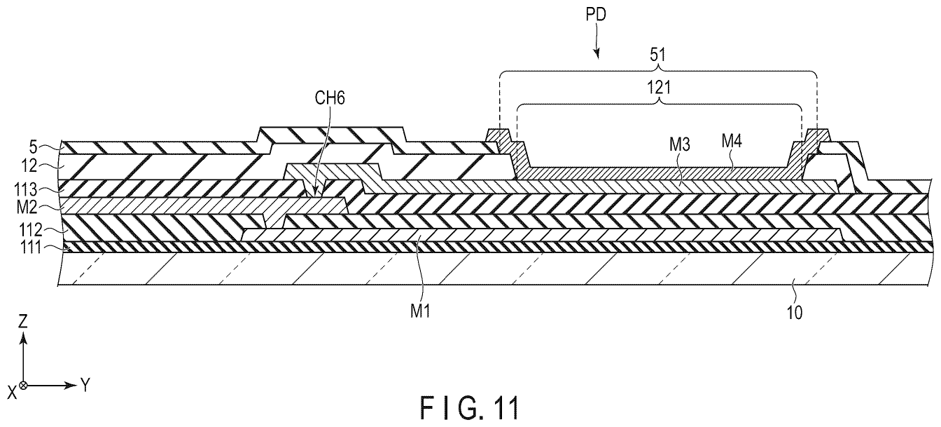

FIG. 9 is a plan view showing a configuration example of an area including a plurality of pads PD in a display device DSP10 according to a comparative example. FIG. 10 is a cross-sectional view of the display device DSP10 taken along the line X-X in FIG. 9. FIG. 11 is a cross-sectional view of the display device DSP10 taken along the line XI-XI in FIG. 9. In FIG. 9, only the aperture 51 of the insulating layers 5 is shown. The apertures 51 and apertures 121 have a rectangular shape elongated along the second direction Y.

In the display device DSP10 of the comparative example, each pad PD is constituted by the metal layer M3 and the metal layer M4. As shown in FIG. 11, in the area overlapping the pad PD, the insulating layer 5 is not brought into contact with the insulating layer 113.

In the display device DSP10 of the comparative example, the insulating layer 12 is continuously formed to around each pad PD. As shown in FIG. 10, the insulating layer 12 is located between each adjacent pair of pads PD.

With this configuration, the insulating layer is brought into contact with the insulating layer 12 between each adjacent pair of pads PD. In other words, the insulating layer 5 is not brought into contact with the insulating layer 113 between each adjacent pair of pads PD. Further, as shown in FIG. 11, also in the area where the slit 123 is formed in this embodiment, the insulating layer 5 is brought into contact with the insulating layer 12.

The adhesion strength between the insulating layer 5, which is an inorganic insulating layer, and the organic insulating layer 12, which is an organic insulating layer, is weaker than the adhesion strength between inorganic insulating layers themselves. With this configuration, in the display device DSP10, the insulating layer 5 can be easily peeled off from the insulating layer 12. Such peeling off lowers the reliability of the display device.

By contrast, in the display device DSP of this embodiment, the insulating layer 5 is brought into contact with the insulating layer 113, which is an inorganic insulating layer in the area overlapping the pad portions 79. With this configuration, the adhesion between the insulating layer 5 and the underlying layer is improved, and peeling off of the insulating layer 5 can be suppressed.

Further, in this embodiment, the insulating layer 5 is in contact with the insulating layer 113 between each adjacent pair of pad portions 70 and in the slits 123, 125, and 127. With this configuration, it is also possible to suppress the peeling off of the insulating layer 5 between each adjacent pair of pad portions 70 and in the slits 123, 125, and 127.

As a result, in the peripheral area SA, the area of the portion that could be the starting point for peeling (the interface between the insulating layer 5 and the insulating layer 12) can be reduced, and the peeling off of the insulating layer 5 can be suppressed. Thus, according to this embodiment, it is possible to suppress the lowering of the reliability of the display device DSP.

In the display device DSP10 of the comparative example, the pads PD are connected to the insulating layer 12 formed therearound, as shown in FIGS. 9 and 11. With this configuration, moisture can easily penetrate to the pads PD from the surrounding area via the insulating layer 12.

The term “moisture” used here means, for example, moisture in the air (outside air). In FIG. 9, a path of moisture intrusion is indicated by an arrow W. The moisture penetrated may corrode the metal layers M3 and M4 that constitute the pad PD. Such corrosion may cause the insulation layer 5 and the metal layer M4 to peel off.

In this embodiment, the cover portion P12 is separated from the insulating layer 12 formed therearound. With this configuration, moisture cannot easily penetrate to the pads PD from the outside, as indicated by the arrow W in FIG. 5. As a result, corrosion of the metal layer M4, which can cause peeling off, is less likely to occur. From this point of view as well, according to this embodiment, it is possible to suppress a decrease in the reliability of the display device DSP.

In this embodiment, the insulating layer 12 covers the entire circumferential edge portion M3E of the metal layer M3, as shown in FIG. 8. In other words, the circumferential edge portion M3E of the metal layer M3 is not exposed. With this configuration, it is possible to prevent undesirable erosion of the aluminum layer, which may be caused by the etching solution used in the process of forming the lower electrode on the insulating layer 12.

In this embodiment, the metal layer M2 does not overlap the slit 123, as shown in FIG. 8. With this configuration, it is possible to prevent undesirable etching of the metal layer M2 (disconnection of the metal layer M2), which may be caused by the etching solution used in the area overlapping the slit 123 during the process of forming the slit 123 in the manufacturing process.

In this embodiment, the insulating layer 5 covers the circumferential edge portion 121E of each aperture 121 of the insulating layer 12. With this configuration, it is possible to suppress undesirable erosion (dissipation) of the insulating layer 12 during the process step of forming the apertures 51 of the insulating layer 5 in the manufacturing process.

As explained above, according to the configuration of this embodiment, it is possible to provide a display device DSP that can suppress a decrease in reliability. In addition, various other advantageous effects can be obtained from this embodiment.

Next, other embodiments will be explained. In the configurations of the following embodiments, similar parts and structure to those of the first embodiment can be applied to parts that are not specifically mentioned.

### Second Embodiment

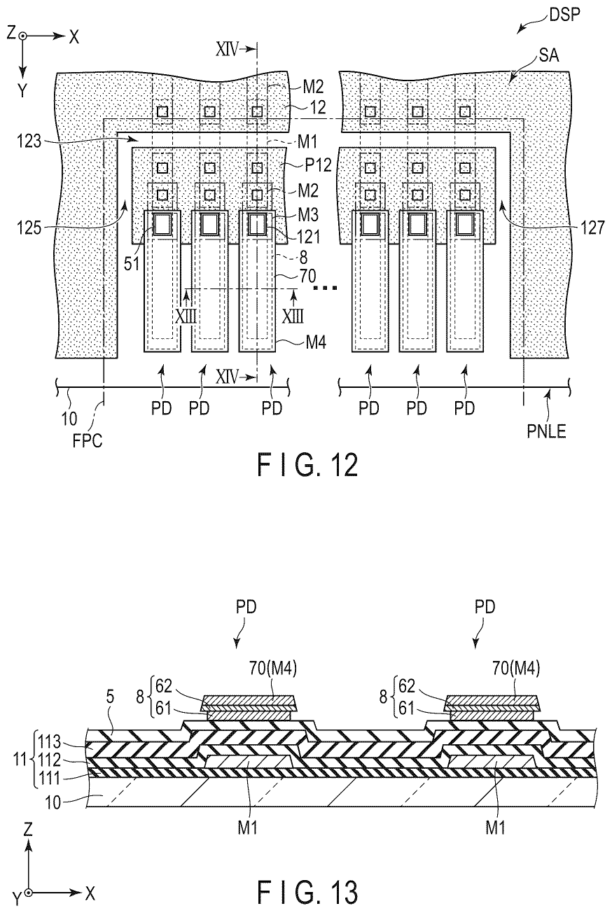

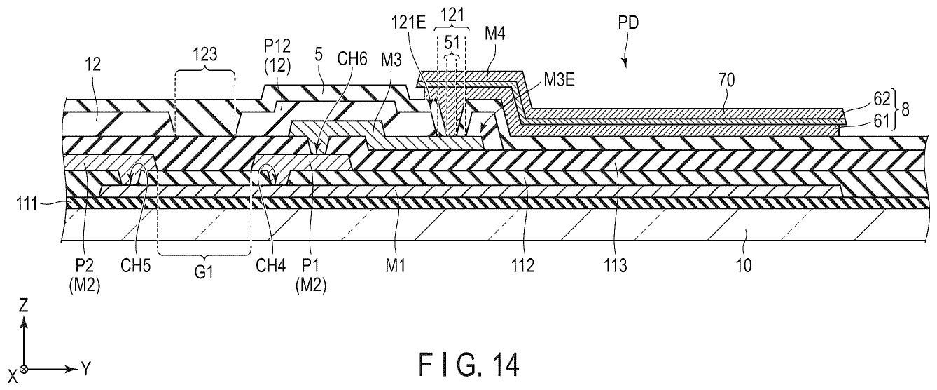

FIG. 12 is a plan view showing a configuration example of an area including a plurality of pads PD in the display device DSP of this embodiment. FIG. 13 is a cross-sectional view of the display device DSP taken along the line XIII-XIII in FIG. 12. FIG. 14 is a cross-sectional view of the display device DSP taken along the line XIV-XIV in FIG. 12. The embodiment is different from the first embodiment in that the display device DSP further comprises a partition 8 formed in the peripheral area SA.

In this embodiment, the partition 8 corresponds to the second partition. The partition 8, together with the pad portions 70 of the metal layer M4, constitutes the pad PD. The partition 8 is disposed between the insulating layer 5 and the metal layer M4. As shown in FIGS. 13 and 14, the partition 8 is brought into contact with each of the insulating layer 5 and the metal layer M4.

The partition 8 includes a lower portion 61 and an upper portion 62, which are configured as in the case of the partition 6. In the partition 8 as well, the upper portion 62 protrudes from the side surfaces of the lower portion 61. The lower portion 61 is in contact with the insulating layer 5.

Further, the lower portion 61 is brought into contact with the metal layer M3 via the apertures 51 and 121. In other words, the lower portion 61 and the upper portion 62 are electrically connected to the metal layer M3. The upper portion 62 is in contact with the metal layer M4 (the pad portion 70). That is, the metal layer M4 is electrically connected to the metal layer M3 via the partition 8.

In the example shown in FIGS. 13 and 14, the metal layer M4 is disposed on the upper portion 62, but the metal layer M4 may as well be arranged to cover at least a part of the lower portion 61. In the area overlapping the pad portion 70, the insulating layer 113, the insulating layer 5, the lower portion 61, the upper portion 62, and the pad portion 70 are stacked one on another in this order along the third direction Z.

With the configuration of this embodiment, advantageous effects similar to those of the first embodiment can be obtained. Further, in this embodiment, the display device DSP further comprises the partition 8. Therefore, the thickness of the pad PD is greater as compared to that of the first embodiment.

Incidentally, when mounting a flexible printed circuit board FPC on a plurality of pads PD, for example, an anisotropic conductive film may be used as an adhesive in some cases. Anisotropic conductive films contain conductive particles. In the configuration of this embodiment, when mounting a flexible printed circuit board FPC, the partition 8 is sunk, and at this time, the conductive particles are pressed into the pad portions 70, thereby improving the pressure bonding strength. Thus, it facilitates the mounting of the flexible printed circuit board FPC on the pads PD. As a result, the reliability of the display device DSP can be improved.

Based on the display devices described above as embodiments of the invention, a person having ordinary skill in the art may achieve display devices with arbitral design changes; however, as long as they fall within the scope and spirit of the present invention, all of such display devices are encompassed by the scope of the present invention. A skilled person would conceive various changes and modifications of the present invention within the scope of the technical concept of the invention, and naturally, such changes and modifications are encompassed by the scope of the present invention. For example, if a skilled person adds/deletes/alters a structural element or design to/from/in the above-described embodiments, or adds/deletes/alters a step or a condition to/from/in the above-described embodiment, as long as they fall within the scope and spirit of the present invention, such addition, deletion, and altercation are encompassed by the scope of the present invention.

Furthermore, regarding the present embodiments, any advantage and effect those will be obvious from the description of the specification or arbitrarily conceived by a skilled person are naturally considered achievable by the present invention.

What is claimed is:

1. A display device comprising:
a substrate;
a first inorganic insulating layer disposed above the substrate and over a display area in which a plurality of display elements are disposed and a peripheral area which surrounds the display area;
an organic insulating layer disposed on the first inorganic insulating layer;
a lower electrode disposed on the organic insulating layer in the display area;
a second inorganic insulating layer disposed on the organic insulating layer and overlapping a circumferential edge portion of the lower electrode;
an organic layer including a light emitting layer and disposed on the lower electrode;
an upper electrode disposed on the organic layer;
a plurality of first metal layers disposed on the first inorganic insulating layer and aligned along an end of the substrate, in the peripheral region; and
a plurality of second metal layers electrically connected to the first metal layers above the second inorganic insulating layer in the peripheral region,
wherein
the second metal layer includes pad portions extending toward the end of the substrate beyond the first metal layer, and
the second inorganic insulating layer is in contact with the first inorganic insulating layer in an area overlapping the pad portions.

2. The display device of claim 1, wherein
the second inorganic insulating layer is in contact with the pad portions in the area.

3. The display device of claim 1, further comprising:
a first partition disposed between each adjacent pair of the plurality of display elements; and
a second partition disposed between the second inorganic insulating layer and the pad portions,
wherein
the first partition and the second partition each includes a lower portion having electrical conductivity and an upper portion protruding from side surfaces of the lower portion.

4. The display device of claim 3, wherein
the lower portion of the second partition is in contact with the second inorganic insulating layer in the area, and
the upper portion of the second partition is in contact with the pad portions in the area.

5. The display device of claim 4, wherein
the lower portion of the second partition is electrically connected to the plurality of first metal layers.

6. The display device of claim 1, wherein
the second inorganic insulating layer is in contact with the first inorganic insulating layer between each adjacent pair of the pad portions.

7. The display device of claim 1, wherein
the organic insulating layer comprises a first aperture overlapping a respective one of the plurality of first metal layers, and
the second inorganic insulating layer comprises a second aperture overlapping the first aperture, via which the respective one of the plurality of first metal layers and a respective one of the plurality of second metal layer are in contact with each other.

8. The display device of claim 7, wherein
the second inorganic insulating layer covers a circumferential edge portion of the first aperture.

9. The display device of claim 1, wherein
the organic insulating layer includes a cover portion that covers the plurality of first metal layers in the peripheral area.

10. The display device of claim 9, wherein
the cover portion covers a circumferential edge portion of each of the plurality of first metal layers.

11. The display device of claim 9, wherein
the cover portion is separated from the organic insulating layer formed in the display area.

12. The display device of claim 11, wherein
the organic insulating layer is located between the lower electrode and the plurality of second metal layers, and further comprises a slit formed along the end of the substrate.

13. The display device of claim 12, wherein
the second inorganic insulating layer is in contact with the first inorganic insulating layer in the slit.

14. The display device of claim 12, further comprising:
a third metal layer disposed between the first inorganic insulating layer and the substrate, and electrically connected to the plurality of first metal layer.

15. The display device of claim 14, wherein
the third metal layer does not overlap with the slit.

16. The display device of claim 14, further comprising:
a fourth metal layer disposed between the third metal layer and the substrate, and electrically connected to the third metal layer.

17. The display device of claim 16, wherein
the third metal layer includes a first portion connected to the plurality of first metal layers and the fourth metal layer and a second portion connected to the fourth metal layer.

18. The display device of claim 17, wherein
a gap is formed between the first portion and the second portion.

19. The display device of claim 18, wherein
the fourth metal layer overlaps the slit while interposing the gap therebetween.

20. The display device of claim 16, wherein
the fourth metal layer extends toward the end of the substrate and overlaps the pad portions.
